(19) United States
(12) Patent Application Publication
(10) Pub. No.: US 2018/0212186 A1
(43) Pub. Date: Jul. 26, 2018

(54) PACKAGING LAYER AND PACKAGED DEVICE

(71) Applicant: Wuhan China Star Optoelectronics Technology Co., Ltd., Wuhan,Hubei (CN)

(72) Inventors: Jiangjiang JIN, Shenzhen, Guangdong (CN); Hsiang-lun HSU, Shenzhen, Guangdong (CN); Jinchang HUANG, Shenzhen, Guangdong (CN); Qian JIANG, Shenzhen, Guangdong (CN)

(73) Assignee: Wuhan China Star Optoelectronics Technology Co., Ltd., Wuhan, Hubei (CN)

(21) Appl. No.: 15/319,771

(22) PCT Filed: Dec. 2, 2016
(86) PCT No.: PCT/CN2016/108337

§ 371 Date: Dec. 17, 2016

(30) Foreign Application Priority Data
Nov. 7, 2016 (CN) 201610976727.2

(51) Int. Cl. H01L 51/52

(52) U.S. Cl. CPC H01L 51/5253; H01L 2251/5338; H01L 51/5262

(57) ABSTRACT

The present disclosure teaches a packaging layer, including a first inorganic functional layer, and an organic buffer layer on a top side of the first inorganic functional layer. The top side of the first inorganic functional layer has a number of indentations. A bottom side of the organic buffer layer interfacing the first inorganic functional layer has a number of bulges corresponding to and matching with the indentations. Each bulge is embedded into a corresponding indentation. The present disclosure also teaches a device by packaged the packaging layer.

### BACKGROUND OF THE INVENTION

### 1. Field of the Invention

The present disclosure generally relates to display techniques, and particularly relates to a packaging layer and a packaged device.

### 2. The Related Arts

Organic light emitting diode (OLED) is a new display and lighting technique that has significant market potential for flexible displays and displays of large dimensions. OLED is able to achieve not only high resolution but also, through continuous advancement in material and equipment, photoelectric conversion of 100% internal quantum efficiency. However, only 30% of the light emitted from the light emitting layer of an OLED device may reach outside word as it has to run through layers of higher indices of refraction than that of air such as the organic layer, the functional layer, the substrate, etc. Despite that various research effort has tried to increase light extraction by micro-refraction or diffraction structures (e.g., micro-lenses, scattering layer), the result is not satisfactory. For example, there are problems such as that the packaging layer is not structurally robust, the optical coupling efficiency is inferior, etc.

### SUMMARY OF THE INVENTION

The technical issue addressed by the present disclosure is to provide a packaging layer and a packaged device capable of enhancing optical coupling efficiency and achieving high structural stability.

To resolve technical issue, the present disclosure teaches a packaging layer including a first inorganic functional layer, an organic buffer layer on a top side of the first inorganic functional layer, and a second inorganic functional layer on a top side of the organic buffer layer. The top side of the first inorganic functional layer has a number of indentations. A bottom side of the organic buffer layer interfacing the first inorganic functional layer has a number of bulges corresponding to and matching with the indentations. Each bulge is embedded into a corresponding indentation. The indentations are periodically arranged. The aperture of each indentation gradually shrinks from a top opening along the top side of the first inorganic functional layer to a bottom end inside the first inorganic functional layer.

The second inorganic functional layer is made from at least a material selected from the group consisting of Al203, TiO2, Si3N4, Carbon-doped Si3N4, and SiO2.

The organic buffer layer is made from at least a material selected from the group consisting of acrylic acid, Hexamethyldisiloxane, polyacrylates, polycarbonates, and polystyrene. The first inorganic functional layer is made from at least a material selected from the group consisting of Al203, TiO2, Si3N4, Carbon-doped Si3N4, and SiO2.

The first inorganic functional layer has a thickness between 1 and 2 μm. and the organic buffer layer has a thickness between 4 and 10 μm.

the first inorganic functional layer is formed by providing an inorganic film through Plasma Enhanced Chemical Vapor Deposition (PEVCD), Atomic Layer Deposition (ALD), Pulsed-Layer Deposition (PLD), or sputtering, and then forming the indentations on the inorganic film through photolithography.

The organic buffer layer is formed by coating a film of organic polymeric material on the first inorganic functional layer and filling the indentations through inkjet printing, and then curing the film through ultraviolet light.

The packaging layer further includes an additional first inorganic functional layer and an additional organic buffer layer. The first inorganic functional layers and the organic buffer layers are alternately staked.

To resolve the technical issue, the present disclosure teaches another packaging layer including a first inorganic functional layer, and an organic buffer layer on a top side of the first inorganic functional layer. The top side of the first inorganic functional layer has a number of indentations. A bottom side of the organic buffer layer interfacing the first inorganic functional layer has a number of bulges corresponding to and matching with the indentations. Each bulge is embedded into a corresponding indentation.

The indentations are periodically arranged. The aperture of each indentation gradually shrinks from a top opening along the top side of the first inorganic functional layer to a bottom end inside the first inorganic functional layer.

The packaging layer further includes a second inorganic functional layer on a top side of the organic buffer layer.

The second inorganic functional layer is made from at least a material selected from the group consisting of Al203, TiO2, Si3N4, Carbon-doped Si3N4, and SiO2.

The organic buffer layer is made from at least a material selected from the group consisting of acrylic acid, Hexamethyldisiloxane, polyacrylates, polycarbonates, and polystyrene. The first inorganic functional layer is made from at least a material selected from the group consisting of Al203, TiO2, Si3N4, Carbon-doped Si3N4, and SiO2.

The first inorganic functional layer has a thickness between 1 and 2 μm. The organic buffer layer has a thickness between 4 and 10 μm.

the first inorganic functional layer is formed by providing an inorganic film through Plasma Enhanced Chemical Vapor Deposition (PEVCD), Atomic Layer Deposition (ALD), Pulsed-Layer Deposition (PLD), or sputtering, and then forming the indentations on the inorganic film through photolithography.

The organic buffer layer is formed by coating a film of organic polymeric material on the first inorganic functional layer and filling the indentations through inkjet printing, and then curing the film through ultraviolet light.

The packaging layer further includes an additional first inorganic functional layer and an additional organic buffer layer. The first inorganic functional layers and the organic buffer layers are alternately staked.

To resolve the technical issue, the present disclosure also teaches a packaged device including a to-be-packaged substrate and a packaging layer packaging the to-be-packaged substrate. The packaging layer includes a first inorganic functional layer, and an organic buffer layer on a top side of the first inorganic functional layer. The top side of the first inorganic functional layer has a number of indentations. A bottom side of the organic buffer layer interfacing the first inorganic functional layer has a number of bulges corresponding to and matching with the indentations. Each bulge is embedded into a corresponding indentation.

Compared to prior art, the packaging layer firstly has the first inorganic functional layer formed to provide airtight and watertight functions. Due to the multiple indentations on the top side of the first inorganic functional layer, and the high fluidity of the material for the organic buffer layer, the indentations are completely filled up and the top side of the first inorganic functional layer is flatly covered by the organic buffer layer. The combination of the first inorganic functional layer and the organic buffer layer is able to effectively enhance the optical coupling output, stability, and operational life of the packaged device, in addition to allowing the packaged device to bend, fold, or even roll.

### BRIEF DESCRIPTION OF THE DRAWINGS

To make the technical solution of the embodiments according to the present disclosure, a brief description of the drawings that are necessary for the illustration of the embodiments will be given as follows. Apparently, the drawings described below show only example embodiments of the present disclosure and for those having ordinary skills in the art, other drawings may be easily obtained from these drawings without paying any creative effort. In the drawings:

FIG. 1 is a schematic diagram showing a packaging layer according to an embodiment of the present disclosure; and

FIGS. 2(a) to 2(f) are schematic diagrams showing the various steps of manufacturing a packaged device according to an embodiment of the present disclosure.

### DETAILED DESCRIPTION OF THE PREFERRED EMBODIMENTS

In the following the present disclosure is explained in details through embodiments and accompanied drawings.

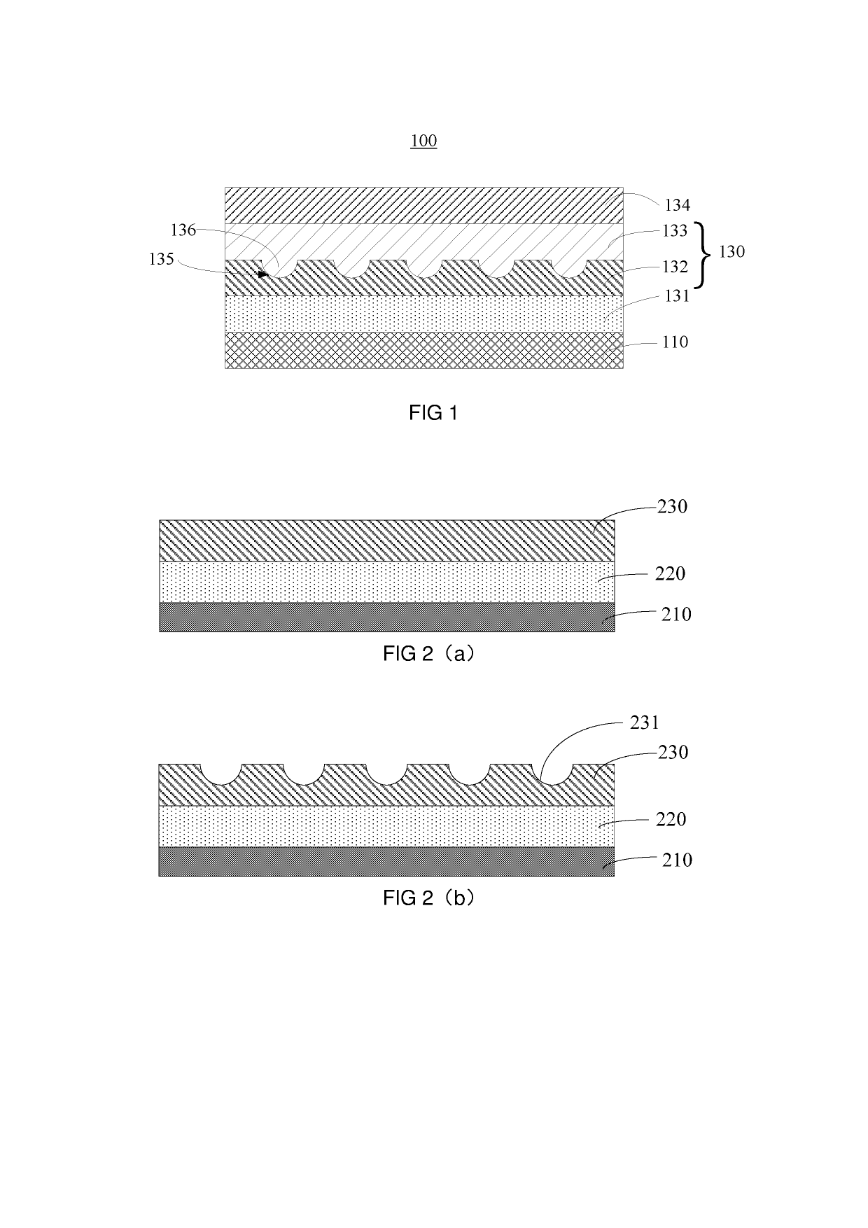

As shown in FIG. 1, a packaged device 100 according to an embodiment of the present disclosure may be, but not limited to, an organic light emitting diode (OLED), an optical tester, a biological sensor, a solar battery, an electronic paper, a smart label, etc. In the present embodiment, the packaged device 100 is an OLED. The packaged device 100 includes a to-be-packaged substrate 110 and a packaging layer 130. The packaging layer 130 includes a base layer 131, a first inorganic functional layer 132, an organic buffer layer 133, and a second inorganic functional layer 134.

The base layer 131 contacts with the to-be-packaged substrate 110. The base layer 131 is made of polyimide (PI).

The first inorganic functional layer 132 covers a top side of the base layer 131. The organic buffer layer 133 in turn covers a top side of the first inorganic functional layer 132. The top side of the first inorganic functional layer 132 has multiple indentations 135 and a bottom side of the organic buffer layer 133 interfacing the first inorganic functional layer 132 has multiple bulges 136 corresponding to and matching with the indentations 135. Each bulge 136 is embedded into a corresponding indentation 135.

The indentations 135 are periodically arranged so as to enhance the optical coupling efficiency.

In alternative embodiments, the indentations 135 may be arranged irregularly.

The first inorganic functional layer 132 is an inorganic film formed by Plasma Enhanced Chemical Vapor Deposition (PEVCD), Atomic Layer Deposition (ALD), Pulsed-Layer Deposition (PLD), or sputtering. The first inorganic functional layer 132 is made from at least a material selected from the group consisting of Al203, TiO2, Si3N4, Carbon-doped Si3N4, and SiO2.

The first inorganic functional layer 132 has a thickness between 1 and 2 μm, such as 1 μm, 1.5 μm, 2 μm, etc.

It should be understandable that the first inorganic functional layer 132 is to provide watertight and airtight functions.

The organic buffer layer 133 is formed by coating a film of organic polymeric material on the first inorganic functional layer 132 and filling the indentations 135 through inkjet printing, and then curing the film through ultraviolet light. The organic buffer layer 133 is made from at least a material selected from the group consisting of acrylic acid, Hexamethyldisiloxane, polyacrylates, polycarbonates, and polystyrene.

It should be understandable that the material for the organic buffer layer 133 has a good fluidity so that the indentations 135 are completely filled, the corresponding bulges 136 are formed, and the top side of the first inorganic functional layer 132 is uniformly and flatly covered.

It should be understandable that the organic buffer layer 133 is made from an organic polymeric material so as to effectively buffer the stress resulted from the packaging layer 130's bending and folding, and to prevent particle contaminants' attachment.

The organic buffer layer 132 has a thickness between 4 and 10 μm, such as 4 μm, 7 μm, 10 μm, etc.

It should be understandable that the first inorganic layer 132 and the organic buffer layer 133 have roughened surfaces, thereby causing change to the index of refraction. In addition, the lighting element (not shown) inside the packaged device 100 has a greater light extraction efficiency as its emitted light crosses fewer boundaries when passing through the first inorganic layer 132 and the organic buffer layer 133.

The second inorganic functional layer 134 is formed using identical technique as the first inorganic functional layer 132. The second inorganic functional layer 134 is made from at least a material selected from the group consisting of Al203, TiO2, Si3N4, Carbon-doped Si3N4, and SiO2.

The second inorganic functional layer 134 has a thickness between 1 and 2 μm, such as 1 μm, 1.5 μm, 2 μm, etc.

It should be understandable that the second inorganic functional layer 134 is to provide additional watertight and airtight functions.

In alternative embodiments, the packaging layer 130 includes two or more alternately stacked first inorganic functional layers 132 and organic buffer layer 133. In other words, the packaging layer 130 includes at least a first inorganic functional layer 132, an organic buffer layer 133, a first inorganic functional layer 132, and an organic buffer layer 133 sequentially arranged in this order.

It should be understandable that, by this repetitive and cyclic arrangement, the optical coupling output of the packaging layer 130 is further enhanced. The stability of the packaging layer 130 is also enhanced, allowing the packaged device to bend, fold, or even roll.

In the packaging layer 130 of the packaged device 100, the first inorganic functional layer 132 firstly formed provides airtight and watertight functions. Due to the multiple indentations 135 on the top side of the first inorganic functional layer 132, and the high fluidity of the material for the organic buffer layer 133, the indentations 135 are completely filled up and the top side of the first inorganic functional layer 132 is flatly covered by the organic buffer layer 133. The combination of the first inorganic functional layer 132 and the organic buffer layer 133 is able to effectively enhance the optical coupling output, stability, and operational life of the packaged device 100, in addition to allowing the packaged device 100 to bend, fold, or even roll. Furthermore, the second inorganic functional layer 134 on a side of the organic buffer layer 133 farther away from the first inorganic functional layer 132 provides additional watertight and airtight effect.

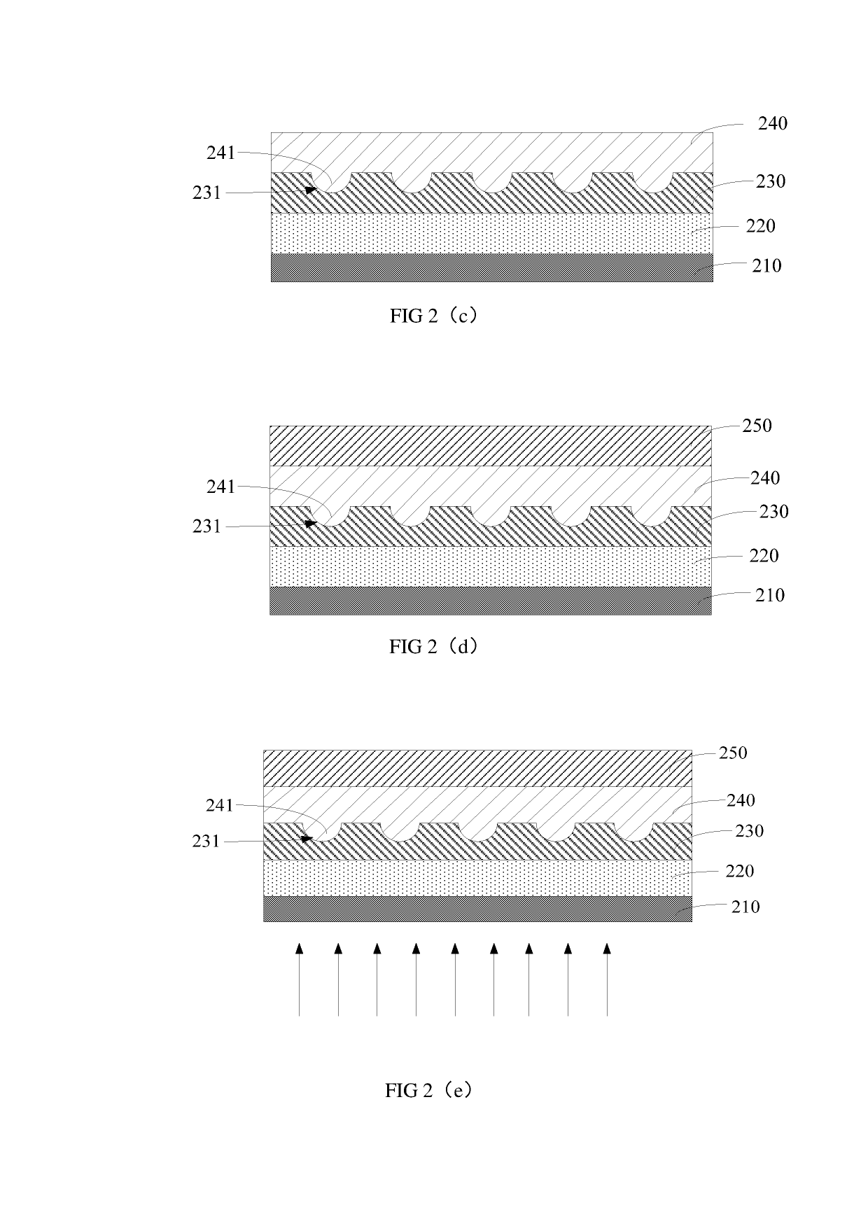

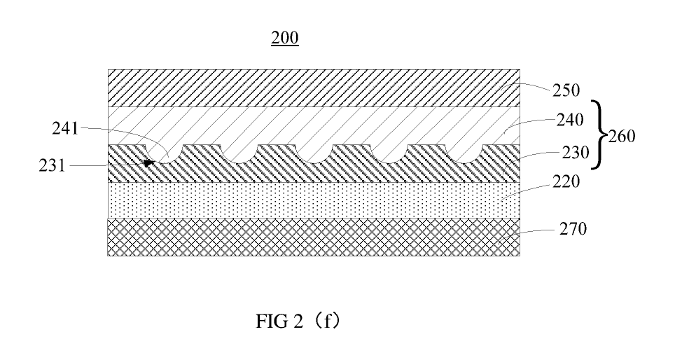

The present disclosure also provides a manufacturing method for a packaged device 200 as shown in FIGS. 2(a) to 2(f), which includes the following steps.

Step S101: providing a substrate 210.

It should be understandable that the substrate 210 may be, but not limited to, a glass substrate.

Step S102: forming a base layer 220 on a top side of the substrate 210, as shown in FIG. 2(a).

The base layer 220 is made of polyimide (PI).

Step S103: forming a first inorganic functional layer 230 on a top side of the base layer 220 farther away from the substrate 210, and forming a plurality of indentations 231 on a top side of the first inorganic functional layer 230 farther away from the base 220, as shown in FIGS. 2(a) and 2(b).

The first inorganic functional layer 230 is an inorganic film formed by Plasma Enhanced Chemical Vapor Deposition (PEVCD), Atomic Layer Deposition (ALD), Pulsed-Layer Deposition (PLD), or sputtering, and then photolithography is applied to form the indentations 231. The first inorganic functional layer 230 is made from at least a material selected from the group consisting of Al203, TiO2, Si3N4, Carbon-doped Si3N4, and SiO2.

The photolithography may employ positive photoresist.

The first inorganic functional layer 230 has a thickness between 1 and 2 μm, such as 1 μm, 1.5 μm, 2 μm, etc.

The indentations 231 are periodically arranged. The aperture of each indentation 231 gradually shrinks from a top opening along the top side of the first inorganic functional layer 230 to a bottom end inside the first inorganic functional layer 230.

Step S104: forming an organic buffer layer 240 on the top side of the first inorganic functional layer 230, as shown in FIG. 2(c), where the indentations 231 are filled up, thereby forming a plurality of bulges 241 along a bottom side of the organic buffer layer 240.

The organic buffer layer 240 is formed by coating a film of organic polymeric material on the first inorganic functional layer 230 and filling the indentations 231 through inkjet printing, and then curing the film through ultraviolet light. The organic buffer layer 240 is made from at least a material selected from the group consisting of acrylic acid, Hexamethyldisiloxane, polyacrylates, polycarbonates, and polystyrene.

The organic buffer layer 240 has a thickness between 4 and 10 μm, such as 4 μm, 7 μm, 10 μm, etc.

Step S105: forming a second inorganic functional layer 250 on a top side of the organic buffer layer 240 farther away from the first inorganic functional layer 230, as shown in FIG. 2(d).

It should be understandable that the second inorganic functional layer 250 is formed using identical technique as the first inorganic functional layer 230.

Step S106: separating the substrate 210 and the base layer 220 through laser scanning, thereby obtaining a packaging layer 260, as shown in FIG. 2(e).

It should be understandable that, through laser scanning, the base layer 220 is more separable from the substrate 210.

Step S107: providing a to-be-packaged substrate 270 and obtaining the packaged device 200 by attaching the packaging layer 260 and the to-be-packaged substrate 270 together, as shown in FIG. 2(f).

It should be understandable that the attachment between the to-be-packaged substrate 270 and the packaging layer 260 may be achieved through heat releasing adhesive.

In alternative embodiments, the steps S103 and S104 may be repeated one or more times before continuing to the step S105 so that the obtained packaged device 200 includes two or more alternately stacked first inorganic functional layers 230 and organic buffer layer 240.

Compared to prior art, the manufacturing method for the packaging layer 260 firstly forms the first inorganic functional layer 230 to provide airtight and watertight functions. Due to the multiple indentations 231 on the top side of the first inorganic functional layer 230, and the high fluidity of the material for the organic buffer layer 240, the indentations 231 are completely filled up and the top side of the first inorganic functional layer 230 is flatly covered by the organic buffer layer 240. The combination of the first inorganic functional layer 230 and the organic buffer layer 240 is able to effectively enhance the optical coupling output, stability, and operational life of the packaged device 200, in addition to allowing the packaged device 200 to bend, fold, or even roll. Furthermore, the second inorganic functional layer 250 on a side of the organic buffer layer 240 farther away from the first inorganic functional layer 230 provides additional watertight and airtight effect to the packaged device 200.

Embodiments of the present disclosure have been described, but not intending to impose any unduly constraint to the appended claims. Any modification of equivalent structure or equivalent process made according to the disclosure and drawings of the present disclosure, or any application thereof, directly or indirectly, to other related fields of technique, is considered encompassed in the scope of protection defined by the clams of the present disclosure.

What is claimed is:

1. A packaging layer, comprising
a first inorganic functional layer;
an organic buffer layer on a top side of the first inorganic functional layer; and
second inorganic functional layer on a top side of the organic buffer layer;
wherein the top side of the first inorganic functional layer has a plurality of indentations; a bottom side of the organic buffer layer interfacing the first inorganic functional layer has a plurality of bulges corresponding to and matching with the indentations; each bulge is embedded into a corresponding indentation; the indentations are periodically arranged; and the aperture of each indentation gradually shrinks from a top opening along the top side of the first inorganic functional layer to a bottom end inside the first inorganic functional layer.

2. The packaging layer as claimed in claim 1, wherein the second inorganic functional layer is made from at least a material selected from the group consisting of Al203, TiO2, Si3N4, Carbon-doped Si3N4, and SiO2.

3. The packaging layer as claimed in claim 1, wherein the organic buffer layer is made from at least a material selected from the group consisting of acrylic acid, Hexamethyldisiloxane, polyacrylates, polycarbonates, and polystyrene; and the first inorganic functional layer is made from at least a material selected from the group consisting of Al203, TiO2, Si3N4, Carbon-doped Si3N4, and SiO2.

4. The packaging layer as claimed in claim 1, wherein the first inorganic functional layer has a thickness between 1 and 2 μm; and the organic buffer layer has a thickness between 4 and 10 μm.

5. The packaging layer as claimed in claim 1, wherein the first inorganic functional layer is formed by providing an inorganic film through Plasma Enhanced Chemical Vapor Deposition (PEVCD), Atomic Layer Deposition (ALD), Pulsed-Layer Deposition (PLD), or sputtering, and then forming the indentations on the inorganic film through photolithography.

6. The packaging layer as claimed in claim 1, wherein the organic buffer layer is formed by coating a film of organic polymeric material on the first inorganic functional layer and filling the indentations through inkjet printing, and then curing the film through ultraviolet light.

7. The packaging layer as claimed in claim 1, further comprising an additional first inorganic functional layer and an additional organic buffer layer; wherein the first inorganic functional layers and the organic buffer layers are alternately staked.

8. A packaging layer, comprising
a first inorganic functional layer; and
an organic buffer layer on a top side of the first inorganic functional layer;
wherein the top side of the first inorganic functional layer has a plurality of indentations; a bottom side of the organic buffer layer interfacing the first inorganic functional layer has a plurality of bulges corresponding to and matching with the indentations; and each bulge is embedded into a corresponding indentation.

9. The packaging layer as claimed in claim 8, wherein the indentations are periodically arranged; and the aperture of each indentation gradually shrinks from a top opening along the top side of the first inorganic functional layer to a bottom end inside the first inorganic functional layer.

10. The packaging layer as claimed in claim 8, further comprising a second inorganic functional layer on a top side of the organic buffer layer.

11. The packaging layer as claimed in claim 10, wherein the second inorganic functional layer is made from at least a material selected from the group consisting of Al203, TiO2, Si3N4, Carbon-doped Si3N4, and SiO2.

12. The packaging layer as claimed in claim 8, wherein the organic buffer layer is made from at least a material selected from the group consisting of acrylic acid, Hexamethyldisiloxane, polyacrylates, polycarbonates, and polystyrene; and the first inorganic functional layer is made from at least a material selected from the group consisting of Al203, TiO2, Si3N4, Carbon-doped Si3N4, and SiO2.

13. The packaging layer as claimed in claim 8, wherein the first inorganic functional layer has a thickness between 1 and 2 μm; and the organic buffer layer has a thickness between 4 and 10 μm.

14. The packaging layer as claimed in claim 8, wherein the first inorganic functional layer is formed by providing an inorganic film through Plasma Enhanced Chemical Vapor Deposition (PEVCD), Atomic Layer Deposition (ALD), Pulsed-Layer Deposition (PLD), or sputtering, and then forming the indentations on the inorganic film through photolithography.

15. The packaging layer as claimed in claim 8, wherein the organic buffer layer is formed by coating a film of organic polymeric material on the first inorganic functional layer and filling the indentations through inkjet printing, and then curing the film through ultraviolet light.

16. The packaging layer as claimed in claim 8, further comprising an additional first inorganic functional layer and an additional organic buffer layer; wherein the first inorganic functional layers and the organic buffer layers are alternately staked.

17. A packaged device, comprising a to-be-packaged substrate and a packaging layer as claimed in claim 8 packaging the to-be-packaged substrate.
